(19) United States
(12) Patent Application Publication
(10) Pub. No.: US 2008/0305579 A1
(43) Pub. Date: Dec. 11, 2008

(54) Method for fabricating semiconductor device installed with passive components

(75) Inventors: Ming-Shan Lin, Taichung (TW); Chien-Chih Sung, Taichung (TW); Chung-Pao Wang, Taichung (TW); Yung-Chuan Ku, Taichung (TW); Chien-Chih Chen, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/157,123

(22) Filed: Jun. 5, 2008

(30) Foreign Application Priority Data
Jun. 5, 2007 (TW) 096120046

(51) Int. Cl. H01L 21/56

(52) U.S. Cl. 438/114; 257/E21.502

(57) ABSTRACT

A method for fabricating a semiconductor device installed with passive components is provided. The method includes: having at least a passive component make a bridge connection between a ground circuit and a power circuit of each of a plurality of substrate units; electrically connecting a conductive circuit on a cutting path between substrate units to the ground circuit and the power circuit, and forming a short circuit loop; or electrically connecting the conductive circuit on the cutting path between the substrate units to the power circuit and the ground circuit via bonding wires, and forming a short circuit loop; or applying a wire bonding machine to form a stud bump on the power circuit, and then forming a short circuit loop via the power circuit and ground loop of the wire bonding machine; therefore, via the short circuit loop, the passive component is capable of releasing electricity filled therein from previous plasma clean process of substrate units and chips; and grounding the chips and the substrate units and electrically connecting powers and signals to prevent the chips from being damaged due to sudden current impulses resulting from the discharging of the passive components when the passive components are electrically connected to the chips.

### BACKGROUND OF THE INVENTION

1. Field of the Invention

The present invention generally relates to a method for fabricating semiconductor devices, and more specifically, to a method for fabricating a semiconductor device installed with passive components.

2. Description of Related Art

In order to improve electricity quality of traditional semiconductor devices, passive components, such as capacitor, inductors, and resistor, are commonly disposed inside packages; this feature has been disclosed according to claims of U. S. Pat. Nos. 5,311,405, 6,521,997, 6,700,204, and others, wherein if capacitor is used as passive components in prior art, it makes a bridge connection between power end and ground end on substrate, therefore, capacitor's filter function can be used for the purposes of stabilizing voltage and eliminating contaminants.

Please refer to FIGS. 4A through 4B are diagrams of a semiconductor device installed with passive components according to prior art; wherein the semiconductor device comprises a substrate 70, and a plurality of signal bonding fingers 701, ground bonding fingers 721 (or ground rings, not shown in the drawings), ground pads 721′, power bonding fingers 722 (or power rings, not shown in the drawings), and power pads 722′ are disposed on the substrate 70; and then a passive component 72, such as a capacitor, is disposed on the substrate 70 to electrically connect to the ground pad 721′ and the power pad 722′; next, proceed to die bond process, a chip 71 with a plurality of bonding pads 710 is disposed on the substrate 70; subsequently, in a plasma clean process, contaminants on surfaces of the chip 71 and the substrate 70 are eliminated; afterward, in a wire bonding process, each of the bonding pads 710 of the chip 71 is individually and correspondingly electrically connect to one of the ground bonding finger 721 and the power bonding finger 722 and signal bonding fingers 701 on the substrate 70 via bonding wire 73.

However, in the plasma clean process for eliminating contaminants on the chip and the substrate, ionized electron current is often used to bombard surfaces of the chip and substrate for eliminating contaminants, thereby causing the capacitor to be charged; and at the time when corresponding bonding pads 710 on the chip 71 are electrically connected to the ground bonding finger 721 and the power bonding finger 722 via bonding wires, sudden electricity discharge will happen due to loop circuit formed between the passive component 72 and the chip 71, thereby correspondingly and suddenly generating a current pulse, and consequently damaging or burning the chip.

Hence, it is a highly urgent issue in the industry for how to provide a technique, capable of effectively solving the drawbacks of semiconductor devices of prior art as mentioned above, and a fabrication method capable of preventing chip from being damaged due to electricity charging/discharging of a passive component.

### SUMMARY OF THE INVENTION

In view of the disadvantages of the prior art mentioned above, it is a primary objective of the present invention to provide a method for fabricating a semiconductor device installed with passive components, and the method is capable of prevent chip from being damaged due to electricity discharge caused by charged passive component.

It is another objective of the present invention to provide a method for fabricating a semiconductor device installed with passive components, and the method is capable of avoiding happening of sudden current impulse in wire bonding process.

To achieve the aforementioned and other objectives, a method for fabricating a semiconductor device installed with a passive component is provided according to the present invention. The method comprises: providing a substrate modular board with a plurality of substrate units, each of the substrate units is demarcated by cutting paths, and each substrate unit has a chip-bonding zone, a ground circuit, and a power circuit, and a conductive circuit is disposed on the cutting path for each substrate unit, and electrically connecting the conductive circuit to the ground circuit and the power circuit to form a short circuit loop; disposing at least a passive component on the substrate unit, and electrically connecting the passive component to the ground circuit and the power circuit; disposing a chip with a plurality of bonding pads on the chip-bonding zone of the substrate unit; electrically connecting corresponding bonding pads on the chip separately to the ground circuit and the power circuit via bonding wires; electrically connecting the bonding pads not connected to either the ground circuit or the power circuit on the chip to the substrate unit via bonding wires; and then proceeding to packaging process and cutting each of the substrate units apart from one another, and consequently removing the conductive circuits on the cutting paths.

The ground circuit comprises a ground pad and a ground bonding finger connected to each other, and the power circuit comprises a power pad and a power bonding finger connected to each other; the pair of the ground pad and the ground bonding finger and the pair of the power pad and the power bonding finger are separately extending to electrically connect to the conductive circuit on the cutting paths; the passive component is electrically connected to the ground pad and the power pad, and the chip is electrically connected to the ground bonding finger and the power bonding finger via bonding wires; the ground circuit can also be a ground ring, and the power circuit can also be a power ring.

Another preferable embodiment of method for fabricating a semiconductor device installed with passive components of the present invention comprises: providing a substrate modular board with a plurality of substrate units, each of the substrate units is demarcated by cutting paths, the substrate unit having a chip-bonding zone, a ground circuit, and a power circuit, and a conductive circuit is disposed on the cutting paths for each substrate unit; disposing at least a passive component on the substrate unit, and electrically connecting the passive component to the ground circuit and the power circuit of the substrate unit; disposing a chip with a plurality of bonding pads on the chip-bonding zone; electrically connecting the conductive circuit to the ground circuit and the power circuit via bonding wires to form a short circuit loop; electrically connecting corresponding bonding pads on the chip to the ground circuit and the power circuit via bonding wires; electrically connecting the bonding pads not connected to either the ground circuit or the power circuit on the chip to the substrate unit via bonding wires; and then proceeding to packaging process and cutting each of the substrate units apart from one another, and consequently removing the conductive circuits on the cutting path.

The ground circuit comprises a ground bonding pad and a ground pad and a ground bonding finger connected to one another, and the power circuit comprises a power bonding pad and a power pad and a power bonding finger connected to one another, therefore, the passive component makes a bridge connection between the ground pad and the power pad, and the conductive circuit is electrically connected to the ground bonding pad and the power bonding pad via bonding wires, and consequently the passive component forms the short circuit loop; and the chip is electrically connected to the ground bonding finger and the power bonding finger via bonding wires; the ground circuit can also be a ground ring, and the power circuit can be a power ring.

A further preferable embodiment of method for fabricating a semiconductor device installed with passive components of the present invention comprises: providing a substrate unit, the substrate unit has a chip-bonding zone, a ground circuit, and a power circuit; disposing at least a passive component on the substrate unit, and electrically connecting the passive component to the ground circuit and the power circuit, and then disposing a chip with a plurality of bonding pads on the chip-bonding zone; applying a wire bonding machine to form a stud bump on the power circuit, and consequently having the power circuit contact with ground loop of the wire bonding machine to form a discharging loop; electrically connecting corresponding bonding pads of the chip to the power circuit and the ground circuit via bonding wires; electrically connecting the bonding pads not connected to either the ground circuit or the power circuit on the chip to the substrate unit via bonding wires; subsequently proceeding to a packaging process, and forming an encapsulant to encapsulate the passive component and the chip.

The ground circuit comprises a ground pad and a ground bonding finger connected to each other, and the power circuit comprises a power pad and a power bonding finger and a power bonding pad connected to one another; therefore, the passive component makes a bridge connection between the ground pad and the power pad; and using bonding wire grounding function of a wire bonding machine, the wire bonding machine forms the stud bump on the power bonding pad, and consequently the short circuit (discharging) loop is formed; the corresponding bonding pads of the chip are electrically connected to the ground bonding finger and the power bonding finger via bonding wires; the ground circuit can also be a ground ring, and the power circuit can be a power ring.

In short, compared with the prior art, the method for fabricating a semiconductor device installed with passive components of the present invention mainly has the following features: having a passive component make a bridge connection between the ground circuit and the power circuit; and then directly electrically connecting the ground circuit and the power circuit to a preset conductive circuit located on cutting paths between substrate units to form a short circuit loop; or electrically connecting the ground circuit and the power circuit to the preset conductive circuit on cutting paths between substrate units via bonding wires to form a short circuit loop; or applying a wire bonding machine to form a stud bump on the power circuit, and consequently having the power circuit contact with ground loop of the wire bonding machine, thereby forming a discharging loop; by means of that the passive component is capable of forming a short circuit (discharging) loop, thus electricity filled up inside the passive component due to plasma clean or other factors can be released; subsequently proceeding to an electricity connection process between the chip and the ground, power, and signal of the substrate unit; therefore, at the time when the chip and the passive component are electrically connected to each other, chip damage due to sudden current impulse caused by electricity discharging of the passive component can be avoided.

### BRIEF DESCRIPTION OF DRAWINGS

The present invention can be more fully understood by reading the following detailed description of the preferred embodiments, with reference made to the accompanying drawings, wherein:

FIGS. 1A through 1D are schematic views of a first embodiment of a method for fabricating a semiconductor device installed with passive components according to the present invention;

FIGS. 2A through 2E are schematic views of a second embodiment of a method for fabricating a semiconductor device installed with passive components according to the present invention;

FIGS. 3A through 3D are schematic views of a third embodiment of a method for fabricating a semiconductor device installed with passive components according to the present invention; and

FIGS. 4A and 4B are schematic views of a semiconductor device installed with passive components according to the prior art.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

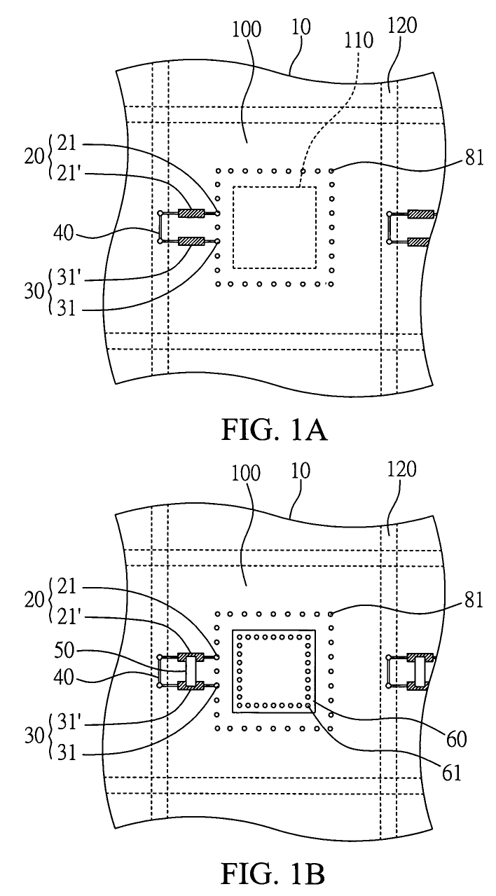

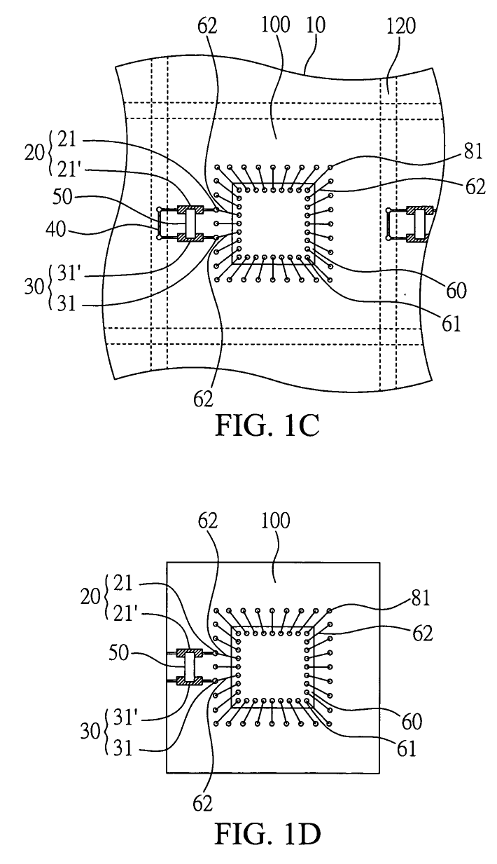

FIGS. 1A through 1D are schematic views of the first embodiment of a method for fabricating a semiconductor device installed with passive components according to the present invention.

As shown in FIG. 1A, providing a substrate modular board 10 with a plurality of substrate units 100, each of the substrate units 100 is demarcated by cutting paths 120, and the substrate unit 100 has a chip-bonding zone 110, a ground circuit 20, and a power circuit 30; the ground circuit 20 comprises a ground pad 21′ and a ground bonding finger 21 connected to each other; the power circuit 30 comprises a power pad 31′ and a power bonding finger 31 connected to each other; a conductive circuit 40 is disposed on the cutting paths 120 for each substrate unit 100; and electrically connecting the conductive circuit 40 to the ground circuit 20 and the power circuit 30.

The ground circuit and the power circuit can also be a ground ring and a power ring (not shown in the drawing) respectively. In addition, the substrate unit 100 comprises a plurality of signal bonding fingers 81 disposed thereon.

As shown in FIG. 1B, soldering at least a passive component 50 such as capacitor on the substrate unit 100 by means of surface mounting technology (SMT), and consequently electrically connecting the passive component 50 to the ground pad 21′ and the power pad 31′ and forming a short circuit loop via the conductive circuit 40, thereby making the passive component 50 such as capacitor incapable of charging electricity; and disposing a chip 60 with a plurality of bonding pads 61 on the chip-bonding zone 110 of the substrate unit 100.

Eliminating contaminants on surfaces of the chip 60 and the substrate unit 100 by means of plasma clean.

As shown in FIG. 1C, proceeding to wire bonding process, electrically connecting corresponding bonding pads 61 on the chip 60 to the ground bonding finger 21 and the power bonding finger 31 via bonding wires 62; and then electrically connecting the bonding pads 61 not connected to either the ground bonding finger 21 or the power bonding finger 31 on the chip 60 to the signal bonding fingers 81 of the substrate unit 100 via bonding wires 62.

As shown in FIG. 1D, proceeding to a packaging process and a cutting process, forming an encapsulant (not shown in the drawing) to encapsulate the passive components and the chips, and then cutting apart each of the substrate units 100 from one another along the cutting paths 120 as well as removing the conductive circuits 40 from the cutting paths 120; and further removing each short circuit loop to recover electricity function of the passive component 50 such as capacitor, thereby forming a plurality of semiconductor devices installed with passive components.

Compared with the prior art, the method for fabricating a semiconductor device installed with passive components according to the present invention has the following features: disposing a ground circuit and a power circuit on each substrate unit, and disposing a conductive circuit on cutting path between substrate units for each substrate unit; electrically connecting the conductive circuit to a passive component and making a bridge connection between power pad of the power circuit and ground pad of the ground circuit, and consequently forming a short circuit loop, thereby making the passive component incapable of charging electricity; subsequently, at the time when the chip is electrically connected to ground bonding finger of the ground circuit and the power bonding finger of the power circuit via bonding wires, since the passive component is incapable of discharging electricity, the passive component will not generate sudden current impulse to damage the chip.

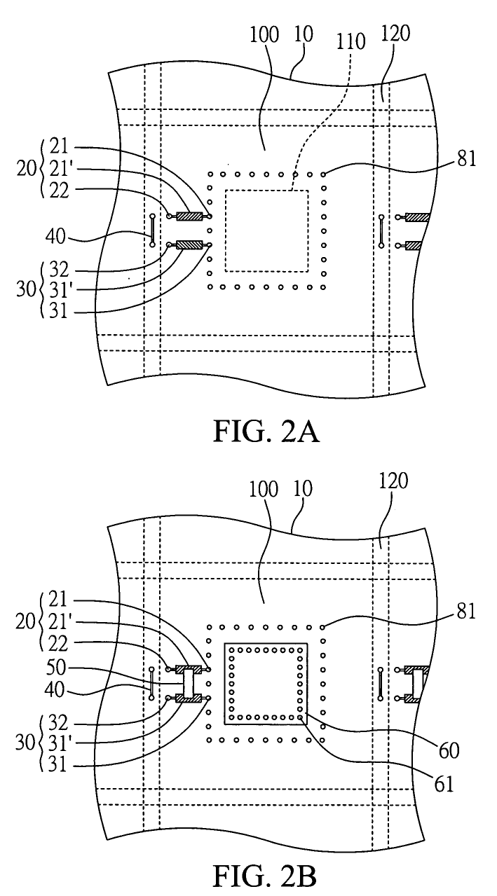

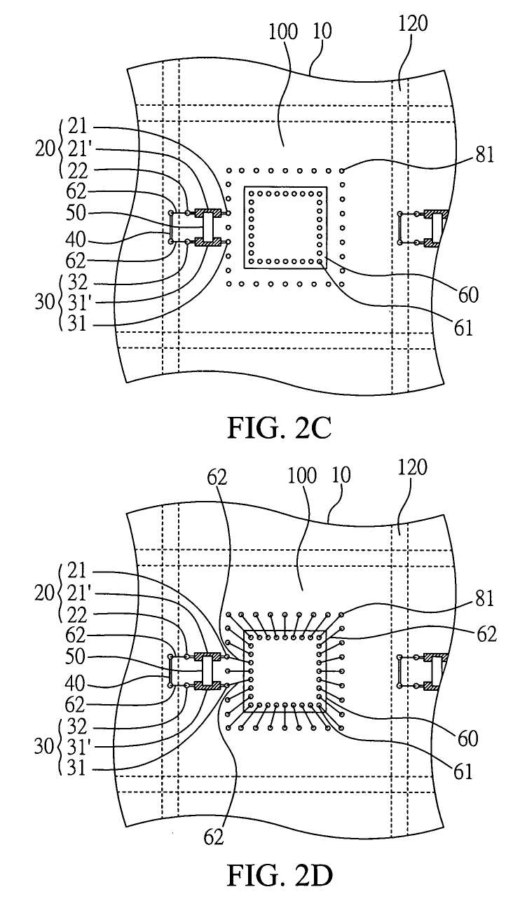

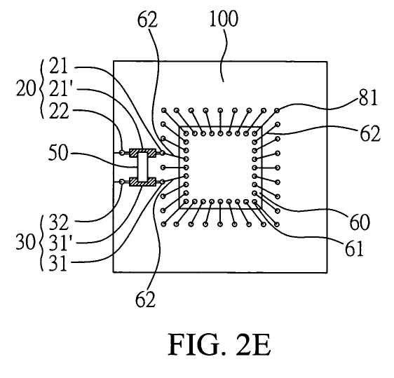

FIGS. 2A through 2E are schematic views of the second embodiment of a method for fabricating a semiconductor device installed with passive components according to the present invention; in order to simplify these schematic views, the present embodiment adopts same labels as those applied in the first embodiment for similar or same elements.

As shown in FIG. 2A, providing a substrate modular board 10 with a plurality of substrate units 100, each of the substrate units 100 is demarcated by cutting paths 120, and each substrate unit 100 comprises a chip-bonding zone 110, a ground circuit 20, and a power circuit 30; the ground circuit 20 comprises a ground pad 21′ and a ground bonding finger 21 and a ground bonding pad 22 connecting to one another, and the power circuit 30 comprises a power pad 31′ and a power bonding finger 31 and a power bonding pad 32; and the cutting paths 120 have conductive circuits 40 disposed thereon.

The ground circuit and the power circuit can also be a ground ring and a power ring (not shown in the drawing) respectively; and each of the substrate units further comprises a plurality of signal bonding fingers 81 disposed thereon.

As shown in FIG. 2B, disposing at least a passive component 50 on the substrate unit 100, and having the passive component 50 make a bridge connection between the power pad 31′ and the ground pad 21′; and disposing a chip 60 with a plurality of bonding pads 61 on the chip-bonding zone 110 of the substrate unit 100.

Next, eliminating contaminants on the surfaces of the chips 60 and the substrate units 100 by means of plasma clean.

Compared with the first embodiment, wherein the ground circuit and the power circuit of the substrate unit are initially electrically connected to the conductive circuit on the cutting paths, therefore, after the passive component is soldered to the ground pad of the ground circuit and the power pad of the power circuit to form a short circuit loop by means of surface mounting technology (SMT), it is impossible to do electricity test for determining soldering status of the passive component; in the present embodiment, since the ground circuit and the power circuit of the substrate unit are not initially electrically connected to the conductive circuit on the cutting paths, after the passive component is solder to the ground pad of the ground circuit and the power pad of the power circuit, it is possible to do electricity test for determining soldering status of the passive component.

As shown in FIG. 2C, having the conductive circuit 40 separately electrically connect to the ground bonding pads 22 of the ground circuit 20 and the power bonding pad 32 of the power circuit 30 via bonding wires 62; consequently having the passive component 50 such as capacitor form a short circuit loop.

As shown in FIG. 2D, proceeding to a wire bonding process between chips and substrate units, electrically connecting corresponding bonding pads 61 of the chip 60 to the ground bonding finger 21 of the ground circuit 20 and the power bonding finger 31 of the power circuit 30, and also electrically connecting the bonding pads 61 not connected to either the ground bonding finger 21 or the power bonding finger 31 on the chip 60 to the signal bonding fingers 81 of the substrate unit 100 via bonding wires 62.

As shown in FIG. 2E, proceeding to a packaging process and a cutting process, forming an encapsulant (not shown in the drawing) to encapsulate passive components and chips, and then cutting apart each of the substrate units 100 from one another along the cutting paths 120, consequently removing the conductive circuits 40 from the cutting paths 120, thereby recovering electricity function of each passive component 50, and a plurality of semiconductor devices installed with passive components are thus fabricated.

In short, the method for fabricating a semiconductor device installed with passive components according to the present invention has the following features: first having a passive component, such as a capacitor, make a bridge connection between ground pad of a ground circuit and power pad of a power circuit; and then electrically connecting power bonding pad of the power circuit and ground bonding pad of the ground circuit to a conductive circuit preset on cutting paths via bonding wires to form a short circuit loop, consequently having the passive component release electricity charged in previous plasma clean process; later on, at the time when chip is electrically connected to the ground circuit and the power circuit via bonding wires, since the passive component is incapable of discharging electricity, the passive component will not generate sudden current impulse to damage the chip.

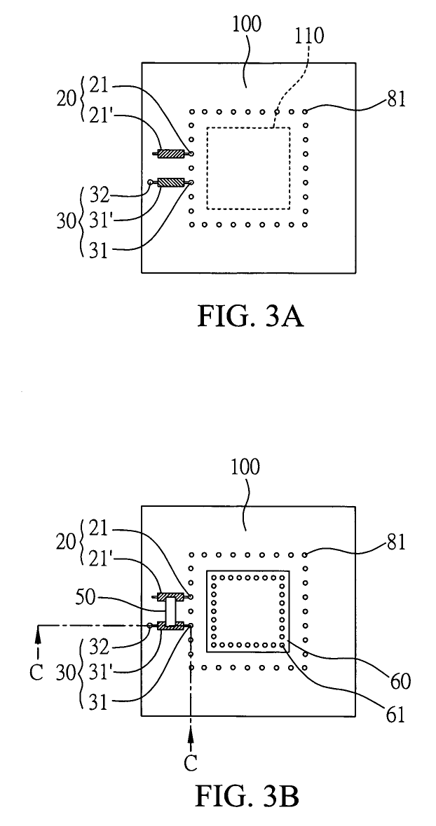

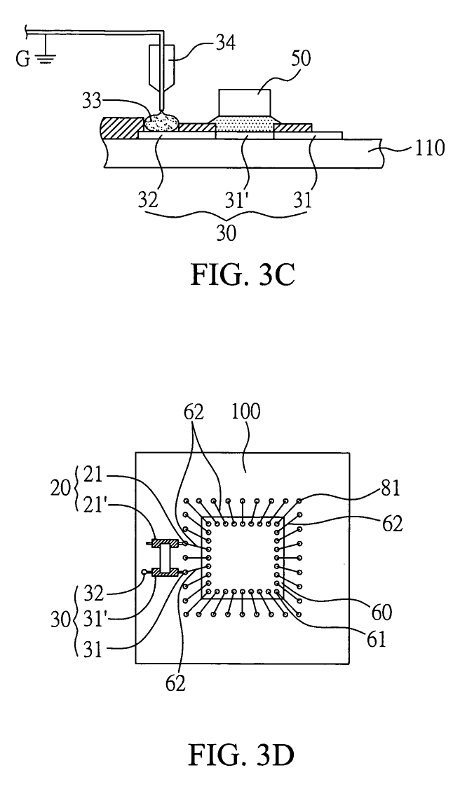

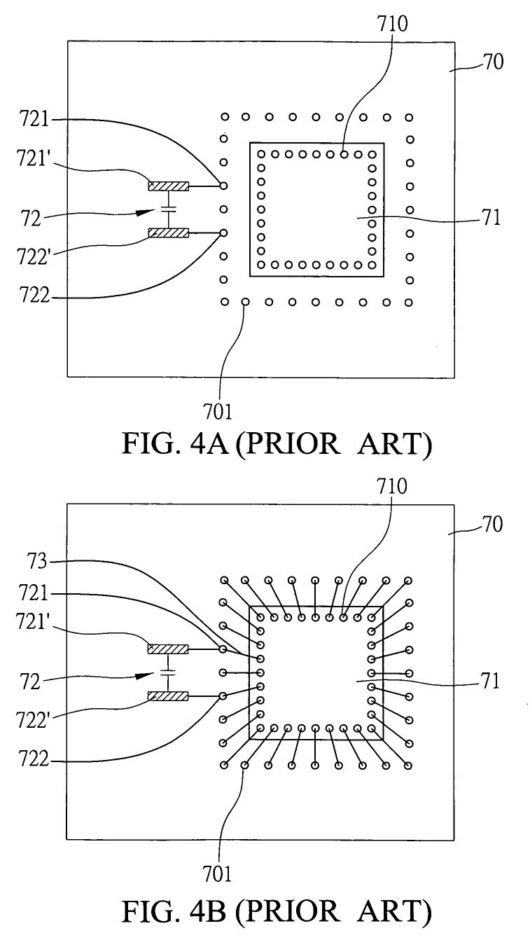

FIGS. 3A through 3D are schematic views of the third embodiment of a method for fabricating a semiconductor device installed with passive components according to the present invention.

As shown in FIG. 3A, providing a substrate unit 100 having a chip-bonding zone 110, a ground circuit 20, and a power circuit 30; the ground circuit 20 comprises a ground pad 21′ and a ground bonding finger 21 connected to each other, and the power circuit 30 comprises a power pad 31′ and a power bonding finger 31 and a power bonding pad 32 connected to one another.

The ground circuit and the power circuit can also be a ground ring and a power ring (not shown in the drawing) respectively; the substrate unit 100 further comprises a plurality of signal bonding fingers 81 disposed thereon.

As shown in FIGS. 3B and 3C, wherein FIG. 3C is a local sectional view diagram of FIG. 3B, disposing at least a passive component 50, a capacitor in this embodiment, on the substrate unit 100, and also having the passive component 50 make a bridge connection between the ground pad 21′ of the ground circuit 20 and the power pad 31′ of the power circuit 30; disposing a chip 60 with a plurality of bonding pads 61 on the chip-bonding zone 110 of the substrate unit 100; and then eliminating contaminants from surfaces of the chip 60 and the substrate unit 100 by means of plasma clean.

Next, using bonding wire grounding function of a wire bonding machine (as indicated by label G in FIG. 3C), applying the wire bonding machine 34 to form a stud bump 33 on the power bonding pad 32; and then forming a short circuit (discharging) loop by contacting the power bonding pad 32 with the grounding function of the wire bonding machine 34; thereby providing the capacitor being electricity charged in previous plasma clean process with means of discharging electricity.

As shown in FIG. 3D, electrically connecting corresponding bonding pads 61 of the chip 60 to the ground bonding finger 21 of the ground circuit 20 and the power bonding finger 31 of the power circuit 30 via bonding wires 62, and also electrically connecting the bonding pads 61 not connected to either the ground bonding finger 21 or the power bonding finger 31 on the chip 60 to the signal bonding fingers 81 of the substrate unit 100 via bonding wires 62.

Subsequently proceeding to a packaging process, forming an encapsulant (not shown in the drawing) to encapsulate the passive component and the chip.

In the present embodiment, the method for fabricating a semiconductor device installed with passive components according to the present invention has the following features: forming a stud bump on the power bonding pad of the power circuit of the substrate unit via ground loop of a wire bonding machine, and consequently forming a short circuit (discharging) loop being for releasing electricity charged by the passive component during plasma clean process, namely, at the time when bonding wire of the wire bonding machine contacts the power bonding pad, consequently having the passive component under a short circuit situation, and then the passive component is capable of discharging electricity; later on, at the time when the chip is electrically connected to the ground circuit and the power circuit, the passive component will not generate sudden current impulse to damage the chip.

In addition, it is feasible to apply the wire bonding machine directly on the power bonding finger instead to form a stud bump, therefore there is no need of disposing power bonding pads.

The foregoing descriptions of the detailed embodiments are intended to disclose the features and functions of the present invention only but are not restrictive of the scope of the present invention. It should be comprehensible to those skilled in the art that any modifications and variations made according to the spirit and principle of the disclosure of the present invention should fall within the scope of the appended claims.

What is claimed is:

1. A method for fabricating a semiconductor device installed with passive components, comprising:
providing a substrate modular board with a plurality of substrate units, the substrate units being demarcated by a plurality of cutting paths, the substrate units each having a chip-bonding zone, a ground circuit, and a power circuit, and the cutting paths each having a conductive circuit, wherein the conductive circuit is electrically connected to the ground circuit and the power circuit to form a short circuit loop;
disposing at least a passive component on each of the substrate units, and electrically connecting the passive component to the ground circuit and the power circuit;
disposing a chip with a plurality of bonding pads at the chip-bonding zone of each of the substrate units;
connecting electrically the bonding pads of the chip to the ground circuit and the power circuit via bonding wires;
connecting electrically the bonding pads not connected to either the ground circuit or the power circuit on the chip to the substrate unit via bonding wires; and
performing an encapsulation process and cutting apart the substrate units from one another so as to remove the conductive circuits from the cutting paths.

2. The method for fabricating a semiconductor device installed with passive components of claim 1, wherein the ground circuit comprises a ground pad and a ground bonding finger connected to each other, and the power circuit comprises a power pad and a power bonding finger connected to each other, with the pair of the ground pad and the ground bonding finger and the pair of the power pad and the power bonding finger being separately electrically connected to the conductive circuit on the cutting path.

3. The method for fabricating a semiconductor device installed with passive component of claim 2, wherein the passive component is electrically connected to the ground pad and the power pad, and the corresponding bonding pads of the chip are electrically connected to the power bonding finger and the ground bonding finger via bonding wires.

4. The method for fabricating a semiconductor device installed with passive component of claim 1, wherein the ground circuit is a ground ring, and the power circuit is a power ring.

5. The method for fabricating a semiconductor device installed with passive component of claim 1, wherein the passive component is a capacitor.

6. The method for fabricating a semiconductor device installed with passive component of claim 1, wherein after the chip is disposed on the substrate unit, further comprising a plasma clean process to eliminate contaminants on surfaces of the chip and the substrate unit.

7. The method for fabricating a semiconductor device installed with passive component of claim 1, wherein the substrate unit has a plurality of signal bonding fingers being for electrically connecting between the bonding pads of the chip and the signal bonding fingers of the substrate unit via bonding wires.

8. A method for fabricating a semiconductor device installed with passive component, comprising:
providing a substrate modular board having a plurality of substrate units, the substrate units being demarcated by a plurality of cutting paths, and the substrate units with each having a chip-bonding zone, a ground circuit, and a power circuit disposed thereon; and the cutting paths with each having a conductive circuit disposed thereon;
disposing at least a passive component on each of the substrate units, and then electrically connecting the passive component to the ground circuit and the power circuit of the substrate unit;
disposing a chip having a plurality of bonding pads on the chip-bonding zone;
electrically connecting the conductive circuit to the ground circuit and the power circuit via bonding wires, and consequently form a short circuit loop;
electrically connecting corresponding bonding pads of the chip to the ground circuit and the power circuit via bonding wires;
electrically connecting the bonding pads not connected to either the ground circuit or the power circuit on the chip to the substrate unit via bonding wires; and
proceeding to a packaging process and cutting apart each of the substrate units from one another, and then removing conductive circuits from the cutting paths.

9. The method for fabricating a semiconductor device installed with passive component of claim 8, wherein the ground circuit comprises a ground bonding pad and a ground pad and a ground bonding finger connected to one another, and the power circuit comprises a power bonding pad and a power pad and a power bonding finger connected to one another.

10. The method for fabricating a semiconductor device installed with passive component of claim 9, wherein having the passive component make a bridge connection between the power pad and the ground pad; electrically connecting the conductive circuit to the ground bonding pad and the power bonding pad via bonding wires, and consequently having the passive component form a short circuit loop; and electrically connecting corresponding bonding pads of the chip to the ground bonding finger and the power bonding finger via bonding wires.

11. The method for fabricating a semiconductor device installed with passive component of claim 8, wherein the ground circuit is a ground ring, and the power circuit is a power ring.

12. The method for fabricating a semiconductor device installed with passive component of claim 8, wherein the passive component is a capacitor.

13. The method for fabricating a semiconductor device installed with passive component of claim 8, wherein after the chips are disposed on the substrate units, further comprising a plasma clean process to eliminate contaminants on surfaces of the chips and the substrate units.

14. The method for fabricating a semiconductor device installed with passive component of claim 8, wherein after electrically connecting the passive component to the ground circuit and the power circuit, proceeding to electricity test process to determine connecting status of the passive component.

15. The method for fabricating a semiconductor device installed with passive component of claim 8, wherein each of the substrate units has a plurality of signal bonding fingers being for electrically connected to the bonding pads of the chip via bonding wires.

16. A method for fabricating a semiconductor device having passive component, comprising:
providing a substrate unit having a chip-bonding zone, a ground circuit, and a power circuit disposed thereon;
disposing at least a passive component on the substrate unit, and then electrically connecting the passive component to the ground circuit and the power circuit; and disposing a chip having a plurality of bonding pads on the chip-bonding zone;
applying a wire bonding machine to form a stud bump on the power circuit, and consequently having the power circuit contact with a ground loop of the wire bonding machine to form an electricity discharging loop;
electrically connecting corresponding bonding pads of the chip to the ground circuit and the power circuit via bonding wires; and
electrically connecting the bonding pads not connected to either the ground circuit or the power circuit on the chip to the substrate unit via bonding wires.

17. The method for fabricating a semiconductor device having passive component of claim 16 further comprising a packaging process to form an encapsulant being for encapsulating the passive component and the chip.

18. The method for fabricating a semiconductor device having passive component of claim 16, wherein the ground circuit comprises a ground pad and a ground bonding finger connected to each other, and the power circuit comprises a power pad and a power bonding finger and a power bonding pad connected to one another.

19. The method for fabricating a semiconductor device having passive component of claim 18, wherein the passive component makes a bridge connection between the ground pad and the power pad; by using bonding wire grounding function of wire bonding machine, the wire bonding machine is used to form a stud bump on the power bonding pad, and consequently a short circuit loop is formed; and corresponding bonding pads of the chip are electrically connected to the ground bonding finger and the power bonding finger via bonding wires.

20. The method for fabricating a semiconductor device having passive component of claim 16, wherein the ground circuit comprises a ground pad and a ground bonding finger connected to each other, and the power circuit comprises a power pad and a power bonding finger connected to each other; the passive component makes a bridge connection between the ground pad and the power pad; by using bonding wire grounding function of a wire bonding machine, the wire bonding machine is used to form a stud bump on the power bonding finger, consequently a short circuit loop is formed; and corresponding bonding pads of the chip are electrically connected to the ground bonding finger and the power bonding finger via bonding wires.

21. The method for fabricating a semiconductor device having passive component of claim 16, wherein the ground circuit is a ground ring, and the power circuit is a power ring.

22. The method for fabricating a semiconductor device having passive component of claim 16, wherein after the chip is disposed on the substrate unit, further comprising a plasma clean process to eliminate contaminants on surfaces of the chip and the substrate.

23. The method for fabricating a semiconductor device having passive component of claim 16, wherein the passive component is a capacitor.

24. The method for fabricating a semiconductor device having passive component of claim 16, wherein the substrate unit has a plurality of signal bonding fingers, and said plurality of signal bonding fingers are for electrically connecting to the bonding pads of the chip via bonding wires.
